(19) United States
(12) Patent Application Publication
(10) Pub. No.: US 2025/0157878 A1
(43) Pub. Date: May 15, 2025

(54) ELECTRONICS MODULE COMPRISING A PULSATING HEAT PIPE WITH A CHANNEL STRUCTURE

(71) Applicant: Siemens Aktiengesellschaft, 80333 München (DE)

(72) Inventors: VLADIMIR DANOV, Erlangen (DE); STEFAN PFEFFERLEIN, Heroldsberg (DE); FLORIAN SCHWARZ, Gerhardshofen (DE); STEFAN STEGMEIER, München (DE)

(73) Assignee: Siemens Aktiengesellschaft, 80333 München (DE)

(21) Appl. No.: 18/720,278

(22) PCT Filed: Nov. 8, 2022
(86) PCT No.: PCT/EP2022/081067

§ 371 Date: Jun. 14, 2024

(30) Foreign Application Priority Data
Dec. 16, 2021 (EP) 21215164.1

(51) Int. Cl. H01L 23/427; H01L 21/48; H05K 7/20

(52) U.S. Cl. CPC H01L 23/427; H01L 21/4878; H05K 7/20936

(57) ABSTRACT

An electronics module includes a pulsating heat pipe having a main body and a channel structure which is at least partially formed in the main body and in which a heat transfer medium is arranged. The main body includes a recess and is made at least partially of a dielectric material. An electronic component is thermally conductively connected to the heat transfer medium and designed as a vertical power semiconductor. A metal rib is secured in the recess and designed to protrude over a surface of the main body. The metal rib is in direct contact with the heat transfer medium.

The invention relates to an electronics module comprising a pulsating heat pipe with a channel structure, in which a heat transfer medium is arranged, and at least one electronic component that is thermally conductively connected to the heat transfer medium.

The invention further relates to a power converter with at least one such electronics module.

The invention additionally relates to a method for producing an electronics module comprising a pulsating heat pipe with a channel structure, in which a heat transfer medium is arranged, and at least one electronic component that is thermally conductively connected to the heat transfer medium.

Such electronics modules are employed for example in a power converter and can comprise active and/or passive electronic components. An electronics module can inter alia be a power semiconductor module, a module for digital signal processing or else a shunt module. A power converter should be understood for example to mean a rectifier, an inverter, a converter or a d.c.-d.c. converter.

With the increasing miniaturization in mounting and connection technology, for example thanks to planar mounting and connection technology, the power density in electronics modules is increasing. In order to avoid electronic failures due to thermal overloads, use is made for example of a pulsating heat pipe (PHP), also known as an oscillating heat pipe (OHP). A pulsating heat pipe is a device for heat transfer with a closed channel structure in which is arranged a heat transfer medium that forms alternating vapor segments and liquid segments along the channel structure due to the surface tension of the heat transfer medium. These vapor and liquid segments are excited to pulsate or oscillate by a temperature gradient. At a heat source, the vapor segments expand because of the higher temperature; moreover, liquid heat transfer medium boils there and absorbs latent heat. At a heat sink, the vapor segments shrink due to condensation of the gaseous heat transfer medium and in this case give off latent heat. The local temperature and pressure differences drive the constant pulsation or oscillation of the vapor and liquid segments.

Published patent application EP 3 823 018 A1 describes an electronics module. The electronics module comprises a pulsating heat pipe with a channel structure, in which a heat transfer medium is arranged, and at least one electrical component that is in direct contact with the heat transfer medium and/or is connected to an electrically conductive contact element that is in direct contact with the heat transfer medium.

Against this backdrop, the object of the invention is to specify an electronics module which enables improved cooling compared to the prior art.

This object is inventively achieved by an electronics module comprising a pulsating heat pipe with a channel structure, in which a heat transfer medium is arranged, and at least one electronic component that is thermally conductively connected to the heat transfer medium, wherein the pulsating heat pipe has at least one main body, in which the channel structure is at least partially formed, wherein the main body has at least one recess, wherein in each case a rib is secured in the at least one recess, and protrudes, in particular orthogonally, beyond a surface of the main body.

The object is further inventively achieved by a power converter with at least one such electronics module.

The object is additionally inventively achieved by a method for producing an electronics module comprising a pulsating heat pipe with a channel structure, in which a heat transfer medium is arranged, and at least one electronic component that is thermally conductively connected to the heat transfer medium, wherein the pulsating heat pipe has at least one main body, in which the channel structure is at least partially formed, wherein at least one recess is introduced into the main body, wherein a rib is secured in the at least one recess, and is arranged so as to protrude, in particular orthogonally, beyond a surface of the main body.

The advantages and preferred embodiments listed below in respect of the electronics module can be transferred analogously to the power converter and the production method.

The invention is based on the consideration of improving cooling of at least one electronic component in an electronics module with a pulsating heat pipe, in that at least one rib is introduced into a main body of the pulsating heat pipe and protrudes beyond the main body. Such an electronic component can be inter alia a transistor, for example an insulated gate bipolar transistor (IGBT) or a field effect transistor, a TRIAC, a thyristor, a diode or a passive component such as a capacitor or a resistor, in particular a shunt resistor. The pulsating heat pipe of the electronics module comprises a channel structure which is at least partially formed in the main body. The main body can be made at least partially of a dielectric material and/or at least partially of a metallic material. A heat transfer medium is arranged in channels of the channel structure. For example, the heat transfer medium is perfluoro-N-alkyl-morpholine, which because of its high thermal conductivity, its boiling point and its dielectric properties is well suited as a heat transfer medium of an electronics module.

The at least one electronic component is thermally conductively connected to the heat transfer medium, so that heat emanating from the electronic component can be coupled into the heat transfer medium. The main body has at least one recess, wherein a rib is secured in the at least one recess and protrudes, in particular orthogonally, beyond a surface of the main body. The rib can also be referred to as a lamella and can be made at least partially of a dielectric material and/or at least partially of a metallic material. The rib can further inter alia be designed in the shape of a cuboid. Two or more ribs can also be arranged in a recess. The ribs can be cast inter alia in a main body manufactured from a plastic, pressed into the main body or connected to the main body via a material-bonded, in particular fluid-tight, connection. The ribs arranged in a recess can for example differ in terms of their geometry, their electrical conductivity and/or their thermal conductivity. The surface can be arranged on an outer surface or an inner surface of the main body, in particular in the region of the channel structure. Thus the rib can inter alia project into the channel structure and/or protrude beyond the outer surface of the main body. A rib protruding beyond the main body results in an increased surface area, which improves heat transfer to the environment and thus cooling. Thus thanks to a rib introduced into the main body it is possible to achieve an efficient coupling in or out of heat.

A further form of embodiment provides that the rib is made of a material which has a higher thermal conductivity than a material of the main body. The main body can be made inter alia of a polymer, while the rib is made of a ceramic material, for example aluminum oxide. The rib can in this way act as a heat conduction structure, so that an improved coupling in or out of heat can be achieved. Furthermore, thanks to the higher thermal conductivity it is possible to achieve more efficient cooling.

A further form of embodiment provides that the rib is made of a metallic material. For example, the rib contains copper, silver and/or aluminum. Such metallic materials have a high thermal conductivity, as a result of which it is possible to achieve more efficient cooling.

A further form of embodiment provides that the metal rib is associated with a metal heat sink. For example, a metal heat sink is formed by a plurality of metal ribs, in particular arranged in parallel to one another, which produce a transition to a flow of cooling fluid. Because of the increase in surface due to the metal ribs, more efficient cooling is achieved.

A further form of embodiment provides that the rib is in direct contact with the heat transfer medium. For example, the rib extends into at least one channel of the channel structure. In particular, when a metal rib is used an improved transfer of heat is achieved.

A further form of embodiment provides that at least one rib protrudes beyond the main body on both sides. In particular, at least one rib protrudes beyond opposing surfaces of the main body, so that the surface is additionally enlarged, thereby additionally improving a transfer of heat to the environment.

A further form of embodiment provides that the main body of the pulsating heat pipe is made at least partially of a dielectric material, wherein the at least one electronic component is connected in an electrically insulating and thermally conductive manner to a metal heat sink via the pulsating heat pipe. The main body made of a dielectric material enables the electronic component to be electrically insulated from the metal heat sink. Thanks to the use of an electrically insulating liquid for the 2-phase cooling an additional or improved electrical separation can be achieved. In particular, in the case of an electronics module with vertical power semiconductors, such as IGBTs for example, it is possible to dispense with a dedicated insulation layer, which is normally provided by a DCB substrate, thereby additionally saving costs.

A further form of embodiment provides that the at least one recess is arranged as so to run in the dielectric material of the main body. In particular, when a metal rib is used an improved transfer of heat is achieved.

A further form of embodiment provides that the main body is at least partially coated in a fluid-tight manner. The dielectric material of the main body, for example a polymer, can be permeable for the heat transfer medium, which forms vapor and liquid segments in the pulsating heat pipe, so that the heat transfer medium can evaporate through the dielectric material of the main body. In order to prevent evaporation of the heat transfer medium, the main body is at least partially coated in a fluid-tight manner. Thus in the region of the main body it is possible to dispense with cost-intensive metallic materials without any significant effect on the heat pipe.

A further form of embodiment provides that the main body is at least partially coated with a metallic, ceramic material and/or a vitreous material. Ceramic and vitreous materials have good insulation properties and enable sufficient tightness even with very small layer thicknesses in the range of 5-50 μm. In particular, a vitreous material, for example silicon dioxide, can be applied to a thermally stable plastic by means of a CVD process, in particular by means of a PACVD process (plasma-enhanced chemical vapor deposition), since such a process can typically take place at 200° C. to 500° C. and so the plastic is not destroyed. A coating with a metallic material, for example copper, gold or silver, can be applied inter alia by hot stamping, a PVD process, in particular sputtering, or galvanically. Such processes are simple and inexpensive. Thanks to metallization thicknesses in the range of 6-50 μm, evaporation of the heat transfer medium is effectively prevented.

A further form of embodiment provides that the main body of the pulsating heat pipe comprises at least one fluid-tight insulation body. Such a fluid-tight insulation body can be made inter alia of a ceramic material and enables electrical insulation of the electronic component from the metal heat sink. In particular, in the case of an electronics module with vertical power semiconductors, such as IGBTs for example, it is possible to dispense with a dedicated insulation layer, which is normally provided by a DCB substrate, thereby additionally saving costs. Furthermore, thanks to the fluid-tight insulation body, evaporation of the heat transfer medium is effectively prevented.

A further form of embodiment provides that the at least one electronic component is in contact with the heat transfer medium via a metal foam. The electronic component can in this case be in direct contact with the heat transfer medium via the metal foam, or can be contacted, for example via an electrically conductive contact element, to the metal foam, which is in direct contact with the heat transfer medium. Such a metal foam, in particular an open-pore metal foam, which can be produced for example by means of an LCS process (Lost Carbonate Sintering), can contain inter alia copper and the heat transfer medium can flow through it. Thus the thermal connection of the electronic component to the heat pipe is improved.

A further form of embodiment provides that at least one, in particular metal, rib is arranged so as to run through the metal foam and is in direct contact with the heat transfer medium. Thanks to such an arrangement the thermal connection of the electronic component to the heat pipe is additionally improved.

A further form of embodiment provides that at least one rib is secured in a recess in a force-fit manner, in particular via a press connection. Such a force-fit connection can be produced easily and inexpensively.

The invention is described and explained in greater detail below on the basis of the exemplary embodiments represented in the figures.

It is shown in:

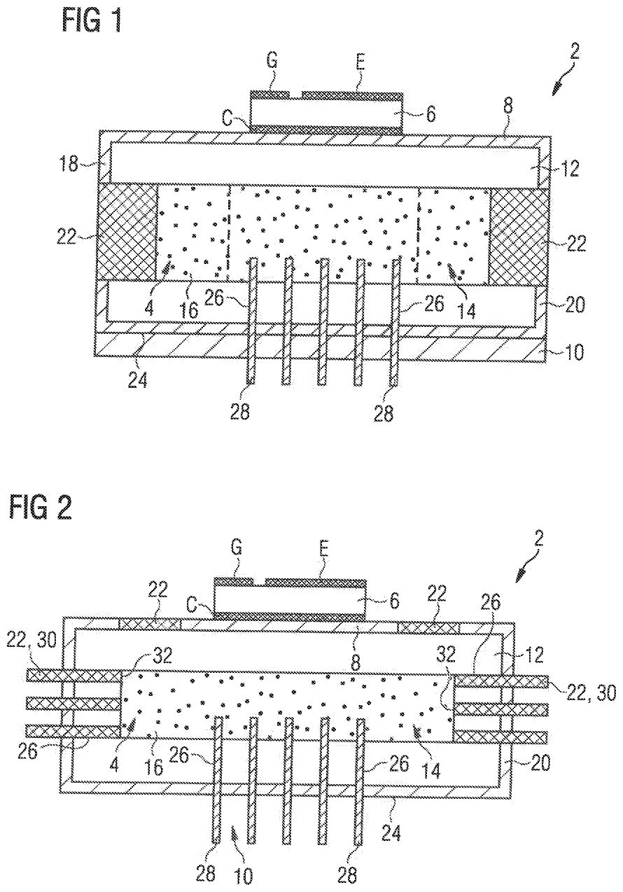

FIG. 1 a schematic representation of a first form of embodiment of an electronics module in cross-section,

FIG. 2 a schematic representation of a second form of embodiment of an electronics module in cross-section,

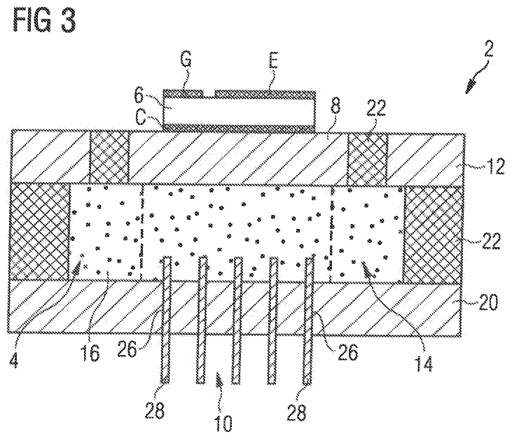

FIG. 3 a schematic representation of a third form of embodiment of an electronics module in cross-section,

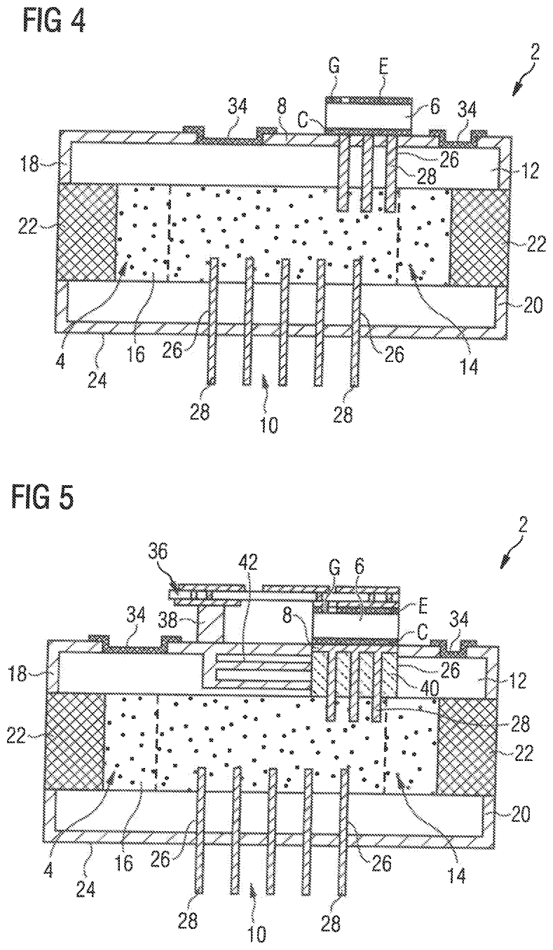

FIG. 4 a schematic representation of a fourth form of embodiment of an electronics module in cross-section,

FIG. 5 a schematic representation of a fifth form of embodiment of an electronics module in cross-section,

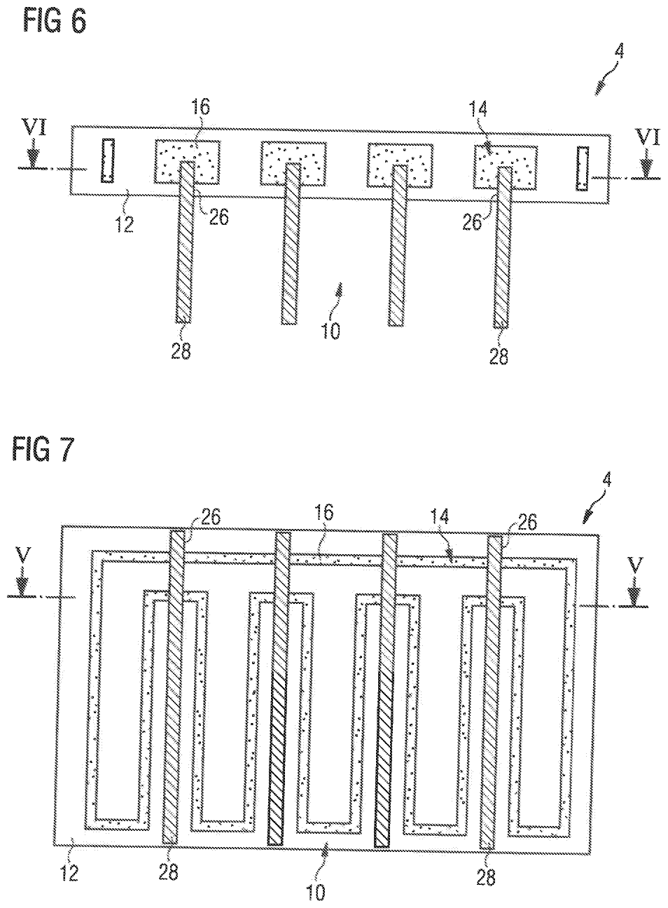

FIG. 6 a schematic representation of a main body of a pulsating heat pipe in cross-section,

FIG. 7 a schematic representation of the main body in a longitudinal section,

FIG. 8 a schematic representation of a first method for securing a rib in a recess in a main body of a pulsating heat pipe for producing an electronics module,

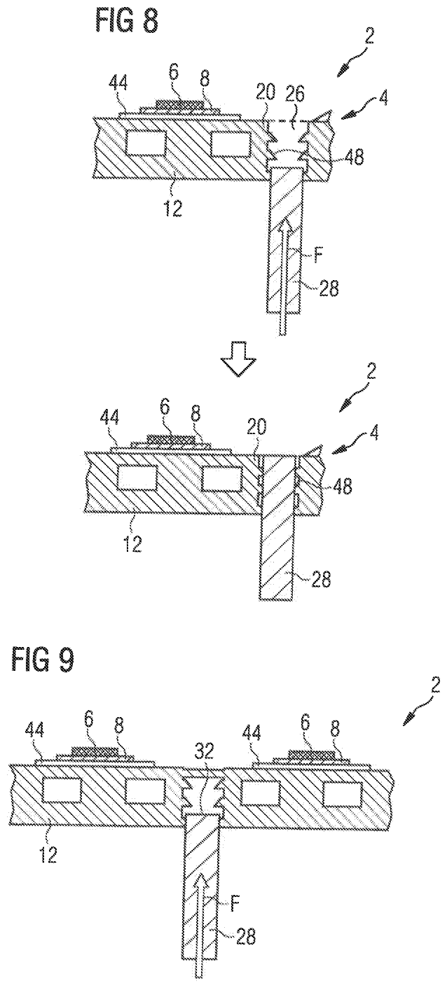

FIG. 9 a schematic representation of a second method for securing a rib in a recess in a main body of a pulsating heat pipe for producing an electronics module,

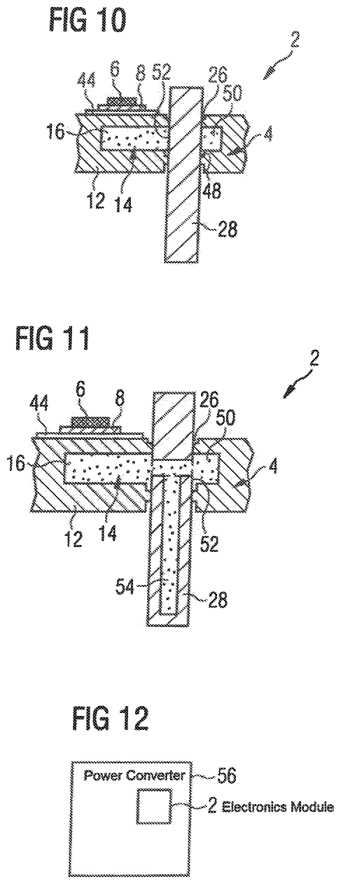

FIG. 10 a segment of a sixth form of embodiment of an electronics module in a schematic cross-sectional representation,

FIG. 11 a segment of a seventh form of embodiment of an electronics module in a schematic cross-sectional representation,

FIG. 12 a schematic representation of a power converter.

The exemplary embodiments explained below are preferred forms of embodiment of the invention. In the exemplary embodiments, the described components of the forms of embodiment each represent individual features of the invention that are to be considered independently of one another and each also develop the invention independently of one another and are thus to be regarded as part of the invention individually or in a combination other than the one shown. Furthermore, the described forms of embodiment can also be supplemented by further features of the invention already described.

The same reference characters have the same meaning in the different figures.

FIG. 1 shows a schematic representation of a first form of embodiment of an electronics module 2 in cross-section, which comprises a pulsating heat pipe 4 and an electronic component 6. By way of example, the electronic component 6 is designed as an insulated gate bipolar transistor (IGBT). Further examples of such electronic components 6 are other types of transistor such as field effect transistors. TRIACs, thyristors, diodes and passive components such as capacitors or resistors, in particular shunt resistors. The IGBT comprises a control terminal, which is designed as a gate terminal G, and load terminals, which are designed as a collector terminal C and an emitter terminal E. On the collector side the IGBT is contacted on an electrically conductive contact element 8, which is designed as a metallization that for example contains copper. In particular, the IGBT is connected to the metallization in a material-bonded manner, for example by a soldered connection or by a sintered connection. The electronic component 6 acts as a heat source, wherein a transfer of heat takes place from the heat source, via the pulsating heat pipe 4, to a heat sink 10. The heat input takes place via the electrically conductive contact element 8. The gate terminal G and the emitter terminal E can be connected to a substrate, inter alia in a material-bonded manner, for example by means of soldering and/or sintering, said substrate not being shown in FIG. 1 for reasons of clarity.

The pulsating heat pipe 4 has a main body 12 in which a planar channel structure 14 is formed, which comprises a closed channel, in particular one running in a meandering manner. In FIG. 1 the channel structure 14 is formed entirely in the main body 12. A heat transfer medium 16 is arranged inside the channel structure 14. Along the closed channel, in particular the one running in a meandering manner, the heat transfer medium 16 alternately forms vapor segments, in which the heat transfer medium 16 is present in a gaseous phase, and liquid segments, in which the heat transfer medium 16 is present in a gaseous phase. The vapor segments and liquid segments are excited in the channel by temperature gradients to pulsating or oscillating movements. For example, the heat transfer medium 16 is perfluoro-N-alkyl-morpholine, which because of its high thermal conductivity, its boiling point and its dielectric properties is well suited as a heat transfer medium 16 of an electronics module 2.

The main body 12 of the pulsating heat pipe 4 is made of a dielectric material which can contain inter alia a polymer, for example polypropylene. Such polymers can be gas-permeable. A metallic fluid-tight coating 18, which is arranged so as to run on a surface 20 of the main body 12, prevents evaporation of the heat transfer medium 16 through the dielectric material of the main body 12. The electrically conductive contact element 8 is part of the metallic fluid-tight coating 18 of the main body 12. Furthermore, the metallic fluid-tight coating 18 of the surface 20 of the main body 12 is connected, in particular in a material-bonded manner, to the heat sink 10, wherein such a connection can be produced inter alia by soldering or sintering. Particularly well suited for the coating are copper, silver, gold or an alloy that contains at least one of these metals. The metallic material can be applied inter alia by thermal metal spraying, in particular by cold gas spraying, plasma spraying, PVD, hot pressing, or by means of electroplating. Typical layer thicknesses of the metallic material are for example in the range of 10 μm to 50 μm. When applying a metallic fluid-tight coating 18 by means of electroplating it is sometimes advantageous if in the case of the above-mentioned polymer of the main body 12 a layer of a catalyst, for example palladium, is provided at least in the region of the coating 18. This enables the metal to accrue directly onto the polymer of the main body 12. For example, a polymer such as ABS or PA is coated with a metallic material, wherein the metallic material is applied by chemical treatment of the polymer, catalytic activation and subsequent galvanic metallization, for example with copper, nickel and/or chromium. For example, the dielectric main body 12 is produced by means of injection molding and the metallic fluid-tight coating 18 is applied in a subsequent step.

In FIG. 1 the electronic component 6 is connected to the metal heat sink 10 in an electrically insulating and thermally conductive manner via a fluid-tight insulation body 22 and an electrically insulating heat transfer medium 16, for example perfluoro-N-alkyl-morpholine, of the pulsating heat pipe 4. Such a fluid-tight insulation body 22 can be made inter alia of a ceramic or vitreous material, for example aluminum oxide or silicon oxide. For example, the fluid-tight insulation body 22 is connected to the main body 12 by an adhesive connection, in particular via a thermally conductive adhesive. Inter alia, in the case of an electronics module 2 with a vertical power semiconductor, such as for example an IGBT, it is possible, thanks to such an arrangement, to dispense with a dedicated insulation layer, which is normally provided by a DCB substrate.

The main body 12 has recesses 26 on a side 24 facing away from the electronic component 6, in each of which a metal rib 28 is secured. The metal ribs 28 are for example made of copper, aluminum or an alloy that contains at least one of these metals, and protrude orthogonally beyond the surface 20 of the main body 12. Thus the metal ribs 28 have a higher thermal conductivity than the main body 12 and act as surface-enlarging heat conducting structures. Furthermore, the metal ribs 28 are arranged so as to run orthogonally into the channel structure 14, so that the metal ribs 28 are in direct contact with the heat transfer medium 16. The metal ribs are associated with the metal heat sink 10.

The metal ribs 28 can inter alia be cast in the dielectric main body 12, pressed into the main body 12 or connected to the main body 12 via a material-bonded, in particular fluid-tight, connection. In addition, the metal ribs 28 in FIG. 1 are connected to the metal heat sink 10, in particular in a material-bonded manner.

FIG. 2 shows a schematic representation of a second form of embodiment of an electronics module 2 in cross-section. In the region of the electronic component 6 the metallic fluid-tight coating 18, which comprises the electrically conductive contact element 8, has fluid-tight insulation bodies 22 which electrically interrupt the metallization, but nevertheless prevent any escape of the heat transfer medium 16. Dielectric ribs 30, which can be made inter alia of a ceramic material, such as aluminum oxide, and are designed as insulation bodies 22, are arranged in recesses 26 in the main body 12. Thus the dielectric ribs 30 have a higher thermal conductivity than the main body 12, which is for example made of a polymer. The dielectric ribs 30 are in direct contact with the heat transfer medium 16 at least via a contact surface 32 and protrude orthogonally beyond the surface 20 of the main body 12. Hence the dielectric ribs 30 act, in addition to their insulation function, as surface-enlarging heat conduction structures. In FIG. 2 the metal heat sink 10 is formed by the metal ribs 28. The further configuration of the electronics module 2 in FIG. 2 corresponds to that in FIG. 1.

FIG. 3 shows a schematic representation of a third form of embodiment of an electronics module 2 in cross-section, wherein the main body 12 is made of a metallic material such as aluminum, copper or an alloy that contains at least one of these metals. The electronic component 6 designed as an IGBT is contacted on the collector side on an electrically conductive contact element 8, which is part of the metallic main body 12. In addition, the channel structure 14 of the pulsating heat pipe 4 is formed entirely in the metallic main body 12, which is interrupted by insulation bodies 22. The metal ribs 28 are arranged in recesses 26 in the main body 12 and are connected to the main body 12, in particular in a material-bonded manner. Alternatively, the metal ribs 28 can inter alia be pressed into the main body 12. The electronic component 6 is connected to the metal heat sink 10 in an electrically insulating and thermally conductive manner via the fluid-tight insulation body 22 and the electrically insulating heat transfer medium 16, for example perfluoro-N-alkyl-morpholine. The metal heat sink 10 is formed in FIG. 3 by the metal ribs 28 and the part of the metal base body 12 that is electrically insulated from the electronic component 6. The further configuration of the electronics module 2 in FIG. 3 corresponds to that in FIG. 1.

FIG. 4 shows a schematic representation of a fourth form of embodiment of an electronics module 2 in cross-section. The metallic fluid-tight coating 18, which comprises the electrically conductive contact element 8, has interruptions in the region of the electronic component 6. In order to prevent an escape of the heat transfer medium 16 in these regions, a fluid-tight dielectric coating 34 is applied, which is designed to be electrically insulating. Such a fluid-tight dielectric coating 34 for example contains a ceramic and/or vitreous material. Ceramic and vitreous materials have good insulation properties and enable sufficient tightness even in the case of very small layer thicknesses in the range of 5-50 μm. In particular, a vitreous material, for example silicon dioxide, can be applied to a thermally stable plastic by means of a CVD process, in particular by means of a PACVD process (plasma-enhanced chemical vapor deposition), since such a . . . process can typically take place at 200° C. to 500° C. and so the plastic is not destroyed.

Furthermore, recesses 26 which run through the main body 12 are arranged underneath the electronic component 6. The recesses 26 can additionally run through the electrically conductive contact element 8. Arranged in the recesses 26 are metal ribs 28 which are connected, in particular in a material-bonded manner, to the electrically conductive contact element 8. The metal ribs 28 are for example made of copper, aluminum or an alloy that contains at least one of these metals. Furthermore, the metal ribs 28 are arranged so as to run orthogonally into the channel structure 14, so that the metal ribs 28 are in direct contact with the heat transfer medium 16 and act as heat conduction structures. The further configuration of the electronics module 2 in FIG. 4 corresponds to that in FIG. 1.

FIG. 5 shows a schematic representation of a fifth form of embodiment of an electronics module 2 in cross-section. By way of example, the electronic component 6 designed as an IGBT is connected by means of planar mounting and connection technology to a substrate 36 which for example can be designed as a printed circuit board (PCB). By way of example, the collector C is connected to the substrate 36 via an, in particular metal, spacer element 38, also called a switch. Alternatively, the IGBT can be flip-chip contacted.

In the region of the contacting with the IGBT the main body 12 has a recess 26 in which, for example three, metal ribs 28 are arranged. The electrically conductive contact element 8 and the metal ribs 28 are designed in one piece in FIG. 5 by way of example and are made from copper, aluminum or an alloy that contains at least one of these metals, wherein the electrically conductive contact element 8 is connected to the fluid-tight metallic coating 18, in particular in a material-bonded manner.

The metal ribs 28 which are arranged in the region of the IGBT are surrounded by an open-pore metal foam 40 which inter alia can contain copper and through which the heat transfer medium can flow, as a result of which the thermal connection of the electronic component 6 to the heat pipe 4 is improved. The metal foam 40 can be produced inter alia by means of an LCS process (Lost Carbonate Sintering). The metal foam 40 can be connected to the electrically conductive contact element 8 and/or the metal rib 28 by means of an electroplating process. In addition, additional conductor tracks 42 are integrated in the main body 12, and can be contacted to the electronic component 6 via the metal foam 40, thus resulting in a heat splay. Furthermore, thanks to the integrated conductor tracks 42 a low-inductance and/or miniaturized structure can be realized. The further configuration of the electronics module 2 in FIG. 5 corresponds to that in FIG. 4.

FIG. 6 shows a schematic representation of a main body 12 of a pulsating heat pipe 4 in cross-section, which is made of a metallic material such as aluminum, copper or an alloy that contains at least one of these metals. FIG. 7 shows a schematic representation of the main body 12 in a longitudinal section. The main body 12 has a planar channel structure 14 which comprises a closed channel, in particular one running in a meandering manner, which is formed entirely in the metallic main body 12.

Metal ribs 28 are arranged in recesses 26 in the main body 12 and are connected to the metallic main body 12, in particular in a material-bonded manner. Alternatively, the metal ribs 28 can inter alia be pressed into the main body 12. An IGBT can for example be contacted on the metallic main body 12 via an electrically insulating and thermally conductive substrate, for example a DCB. The metal ribs 28 are connected to the metallic main body 12 such that they project into the channel structure 14 and are in direct contact with the heat transfer medium 16. The further configuration of the heat pipe 4 in FIG. 6 and FIG. 7 corresponds to that in FIG. 3.

FIG. 8 shows a schematic representation of a method for securing a rib 28 in a recess 26 in a main body 12 of a pulsating heat pipe 4 for producing an electronics module 2. The electronic component 6, which for example is designed as an IGBT and is contacted on an electrically conductive contact element 8, is connected to a metallic main body via an electrically insulating and thermally conductive dielectric layer 44. The rib 28 is for example made of a metallic material and is pressed into the main body 12 by a press-in force F. During the pressing in, connection means 48, for example barbs, are plastically deformed. The recess 26 is designed to be continuous. The rib 28 in FIG. 8 is pressed in so that it is flush with the surface 20 of the main body 12. The further configuration of the electronics module 2 in FIG. 8 corresponds to that in FIG. 3.

FIG. 9 shows a schematic representation of a second method for securing a rib 28 in a recess 26 of a main body of a pulsating heat pipe 4 for producing an electronics module 2. The recess 26 is not designed to be continuous. The rib 28 in FIG. 9 is pressed in so that it touches the main body 12 on an upper contact surface 32. The further configuration of the method corresponds to that in FIG. 8.

FIG. 10 shows a segment of a sixth form of embodiment of an electronics module 2 in a schematic cross-sectional representation. The recess 26 is designed to run continuously through a channel 50 of the channel structure 14, so that the rib 28 is directly in contact with the heat transfer medium via two lateral surfaces 52 and the channel 50 is separated by the rib 28. The further configuration of the electronics module 2 corresponds to that in FIG. 8.

FIG. 11 shows a segment of a seventh form of embodiment of an electronics module in a schematic cross-sectional representation, wherein the rib 28, which inter alia can be made of a metallic or a dielectric material, has a cavity structure 54. The cavity structure 54 of the rib 28 protrudes beyond the lateral surfaces 52 with the heat transfer medium 16 from the channel 50 in a fluidic connection. In particular, heat transfer medium 16 in this way flows through the cavity structure 54 of the rib 28.

FIG. 12 shows a schematic representation of a power converter 56, which by way of example comprises an electronics module 2.

To summarize, the invention relates to an electronics module 2 comprising a pulsating heat pipe 4 with a channel structure 14, in which a heat transfer medium 16 is arranged, and at least one electronic component 6 that is thermally conductively connected to the heat transfer medium 16. In order to enable improved cooling in comparison to the prior art, it is proposed that the pulsating heat pipe 4 has at least one main body 12, in which the channel structure 14 is at least partially formed, wherein the main body 12 has at least one recess 26, wherein in each case a rib 28, 30 is secured in the at least one recess 26, and protrudes, in particular orthogonally, beyond a surface 20 of the main body 12.

What is claimed is:

1.-16. (canceled)

17. An electronics module, comprising:
a pulsating heat pipe including a main body and a channel structure which is at least partially formed in the main body and in which a heat transfer medium is arranged, said main body including a recess and made at least partially of a dielectric material;
an electronic component thermally conductively connected to the heat transfer medium and designed as a vertical power semiconductor, and
a metal rib secured in the recess and designed to protrude beyond a surface of the main body, said metal rib being in direct contact with the heat transfer medium.

18. The electronics module of claim 17, wherein the metal rib protrudes orthogonally beyond the surface of the main body.

19. The electronics module of claim 17, wherein the metal rib is made of a material which has a thermal conductivity that is higher than a thermal conductivity of a material of the main body.

20. The electronics module of claim 17, wherein the metal rib is made of a metallic material.

21. The electronics module of claim 17, further comprising a metal heat sink, said metal rib being connected to the metal heat sink.

22. The electronics module of claim 17, wherein the metal rib extends into a channel of the channel structure.

23. The electronics module of claim 17, wherein the metal rib is designed to protrude beyond the main body on both sides.

24. The electronics module of claim 17, further comprising a metal heat sink, said electronic component being connected to the metal heat sink in an electrically isolating and thermally conductive manner via the pulsating heat pipe, said metal heat sink being formed by a plurality of said metal rib to establish a transition to a cooling fluid flow.

25. The electronics module of claim 24, wherein the plurality of metal ribs are arranged parallel to one another.

26. The electronics module of claim 17, wherein the recess is arranged so as to run in the dielectric material of the main body.

27. The electronics module of claim 17, wherein the main body of the pulsating heat pipe is coated at least partially in a fluid-tight manner.

28. The electronics module of claim 17, wherein the main body of the pulsating heat pipe is coated at least partially with a metallic, ceramic material and/or vitreous material.

29. The electronics module of claim 17, wherein the main body of the pulsating heat pipe comprises a fluid-tight insulation body.

30. The electronics module of claim 17, wherein the metal rib is secured in a force-fit manner in the recess, in particular via a press connection.

31. An electronics module, comprising:
a pulsating heat pipe including a main body and a channel structure which is formed at least partially in the main body and in which a heat transfer medium is arranged, said main body including a recess;
an electronic component thermally conductively connected to the heat transfer medium and designed as a vertical power semiconductor;
a metal rib secured in the recess and designed to protrude beyond a surface of the main body; and
a metal foam via which the electronic component is in contact with the heat transfer medium, said metal rib being designed to run through the metal foam and being in direct contact with the heat transfer medium.

32. The electronics module of claim 31, wherein the metal rib protrudes orthogonally beyond the surface of the main body.

33. The electronics module of claim 31, wherein the metal rib is secured in a force-fit manner in the recess, in particular via a press connection.

34. A power converter, comprising the electronics module as set forth in claim 17.

35. A power converter, comprising the electronics module as set forth in claim 31.

36. A method for producing an electronics module, comprising:
at least partially forming a channel structure in a main body of a pulsating heat pipe, with the main body of the pulsating heat pipe being made at least partially of a dielectric material;
arranging a heat transfer medium in the channel structure of the main body of the pulsating heat pipe;
designing an electronic component as a vertical power semiconductor;
thermally conductively connecting the electronic component to the heat transfer medium;
introducing a recess into the main body of the pulsating heat pipe;
securing a metal rib in the recess such as to protrude, in particular orthogonally, beyond a surface of the main body; and
directly contacting the metal rib with the heat transfer medium.
